(19) United States
(12) Patent Application Publication
(10) Pub. No.: US 2003/0003682 A1
(43) Pub. Date: Jan. 2, 2003

(54) Method for manufacturing an isolation trench filled with a high-density plasma-chemical vapor deposition oxide

(76) Inventors: Hans-Peter Moll, Dresden (DE); Alexander Trueby, Dresden (DE); Andreas Wich-Glasen, Langebrueck (DE)

Correspondence Address: SCHIFF HARDIN & WAITE, 6600 SEARS TOWER, 233 S WACKER DR, CHICAGO, IL, 60606-6473, US

(21) Appl. No.: 10/164,927

(22) Filed: Jun. 6, 2002

(30) Foreign Application Priority Data
Jun. 7, 2001 (DE) 101 27 622.2

(51) Int. Cl. H01L 21/76

(52) U.S. Cl. 438/435; 438/437

(57) ABSTRACT

A method for filling an isolation trench in a semiconductor substrate includes the steps of forming a first silicon oxide layer on sidewalls and the floor of each trench by an oxidation step, forming a second silicon oxide layer on the sidewalls and floor of the trench by a first high-density plasma-chemical vapor deposition process without applying an RF voltage to a wafer so that the ratio of depositing to etching is extremely high and then forming a third silicon oxide layer by a second high-density plasma-chemical vapor deposition process having an RF voltage applied to the wafer so that the ratio of depositing to etching is much lower than in the first-mentioned process.

### BACKGROUND OF THE INVENTION

The present invention is directed to a method for manufacturing an isolation trench filled with a high-density plasma-chemical vapor deposition oxide, which is referred to as an HDPCVD oxide.

Integrated semiconductor products are manufactured by forming integrated circuits on semiconductor wafers. In order to assure a faultless functionability of the semiconductor product, the individual active elements of the integrated circuits, for example field effect transistors or bipolar transistors, must be isolated from one another. This can be achieved, for example, by what is referred to as isolation trenches that are formed in the semiconductor wafer and are subsequently filled with a non-conductive material. These trenches are known as shallow trench isolations and are referred to as STI.

The method of manufacturing a STI structure that is known from the prior art shall be described in greater detail using FIGS. 1A-1D. First, as shown in FIG. 1A, a pad oxide layer 12 is applied on a semiconductor substrate 10. A mask 14 is then applied over this pad oxide layer 12 and silicon nitride is usually deposited by a low-pressure chemical vapor deposition (LPCVD).

After the exposure of the mask 14, a trench 16 having a predetermined depth is etched into the substrate 10 by means of a selective etching step through the pad oxide layer 12 (see FIG. 1B). By means of subsequent oxidation steps, the accessible surface of the substrate is oxidized and an oxide layer 18 is thereby formed on the floor of the trench and at the sidewalls of the trench 16 (see FIG. 1C). Care is thereby exercised to see that the oxide layer 18 is formed to such a thickness that it terminates with the pad oxide layer 12.

Subsequently, a dielectric layer material, preferably silicon oxide, is deposited into the trench 16 and over the surface of the wafer by means of a chemical vapor deposition at a normal pressure, so that an isolation layer 20 is formed. After a compression or a densification step, wherein the isolation layer 20 is compressed or densified in a nitrogen atmosphere at elevated temperatures, a chemical-mechanical polishing (CMP) step is undertaken and, as a result of this step, part of the isolation layer 20 lying above the mask 14 is eroded or removed, as illustrated in FIG. 1D.

In recent years, the complexity of the integrated circuits has greatly increased, so that the size of the circuits have been simultaneously drastically decreased. For this reason, the isolation trenches needed for the separation of the individual active elements were shaped with an aspect ratio that has become greater and greater. However, filling these isolation trenches with a larger aspect ratio, the above-described classic deposition processes, wherein the dielectric material is deposited by chemical vapor deposition at normal pressure, can no longer be used, since, in particular, the deposition of insulation material onto the walls of the isolation trench causes the closure of the trench before the isolation trench is completely filled. The cavities produced by this will prevent optimum isolation properties.

Due to the increasing complexity in the new technology and the shrinking of elements with the increasing aspect ratio of the isolation trenches connected therewith, one was therefore forced to develop new processes for filling the isolation trenches that allows a complete filling, even given a high aspect ratio. Such a process is a high-density plasma (HDP) oxide deposition. Typically, the HDP deposition process comprises a chemical vapor deposition (CVD) with a gas mixture of oxygen, silane and inert gases, such as, for example, argon. In the HDPCVD process, an etching process and a deposition of material occurs simultaneously. In the HDPCVD process, an alternating voltage in a radio-frequency range (RF voltage) is applied to the wafer in the reaction chamber. As soon as the RF voltage is adjacent to the wafer, some of the gas constituents, particularly argon, are ionized in the plasma and accelerated in the direction of the wafer surface. When the ions impact the wafer, material is hurled out of the surface. As a result thereof, dielectric material deposited on the wafer surface is etched off and constrictions, which are formed during the deposition process, are held open. As a result thereof, isolation trenches having a high aspect ratio can also be filled.

FIGS. 2A-2D illustrate such a simultaneous etching and deposition process in greater detail. In FIG. 2A, the beginning of the deposition of the SiO₂ that is formed of the silane (SiH₄) and oxygen on the surface of the wafer 22 is shown. As a result thereof, the isolation trenches 16 are to be filled between the active regions 24. While the SiO₂ deposits on the surface, charged ions impact the dielectric layer 26, which results in an etching of the SiO₂ layer 26 simultaneously with the deposition. However, since the etching rate, given a corner, is approximately 3 to 4 times as high as given a horizontal surface, inclined surfaces 28 (see FIG. 2B) are formed at the corners of the active regions 24 during the deposition process. FIGS. 2C and 2D show the further course of the HDPCVD process with simultaneous etching and deposition until the trench 16 is completely filled.

In the described HDPCVD method, however, a problem can occur that shall be explained in greater detail on the basis of FIGS. 3A and 3B. FIG. 3A shows a substrate 30 having an oxide layer 32 and a nitride layer 34 is deposited on the oxide layer 32. The substrate 30 includes isolation trenches 36, whose walls are covered with an oxide layer 38. FIG. 3A also shows the isolation trenches 36 partially filled with an oxide layer 40. As described above, an etching process simultaneously occurs during the deposition of the oxide layer 40 with a HDPCVD method, and this etching can cause the corners of the isolation trenches 36, the oxide layer 32, the nitride layer 34 and the oxide layer 38 to be damaged, which damage is represented by reference character 42. It is precisely these exposed edges that are at extreme risk for sputter damage due to their exposed position. The situation after the HDPCVD deposition process is shown in FIG. 3B. The isolation trenches 36 are completely filled with oxide layer 40; however, the damaged areas 42 of the oxide layer 32, nitride layer 34 and oxide layer 38 are still present.

FIG. 4 shows an image of a damaged area 42 registered with a transmission electron microscope. This damaged area 42 was produced by a HDPCVD process for filling isolation trenches. Damage of the described type leads to a lowering of the cutoff voltage (array VT), to leakage currents and to a gate oxide degradation (reduced GOX dependability).

U.S. Pat. No. 6,037,018, whose disclosure is incorporated herein by reference thereto, discloses a method with which the above-described damage areas can be prevented. According to this patent, a silicon oxide protective layer 44 is applied onto the oxide layer 38 and the nitride layer 34 (as shown in FIG. 5). To that end, an ozone tetraethylorthosilicate or O₃-TEOS process is implemented at low pressures or an O₃-TEOS process is implemented with a low O₃ concentration. After the application of the silicon oxide layer 44, the same is compressed or densified in a nitrogen atmosphere at a temperature of approximately 1000° C. Subsequently, the isolation trenches are filled with the oxide layer 40 by means of a HDPCVD process. Damage during the HDPCVD process is avoided due to the protective layer 44.

However, the method disclosed by U.S. Pat. No. 6,037,018 exhibits the disadvantage that an additional process step, namely the application of the oxide protective layer 44, must be implemented. In view of the process management in the manufacture of semiconductor components, this causes a considerable added cost in producing the devices.

### SUMMARY OF THE INVENTION

The present invention is based on an object of providing a method for the manufacture of HDPCVD oxide-filled isolation trenches that does not exhibit the disadvantages of the prior art. To achieve this object, the method for manufacturing a HDPCVD oxide-filled isolation trench involves the following steps: forming at least one isolation trench in a semiconductor substrate; forming a first silicon oxide layer at the sidewalls and on the floor of the isolation trench by means of an oxidation step; forming a second silicon oxide layer at the sidewalls and on the floor of the isolation trench by use of a first HDPCVD method, which has been adjusted to carry out a relatively high ratio or relationship of depositing to etching; and then depositing a third silicon oxide layer with a second HDPCVD method to fill the isolation trenches with silicon oxide, wherein the second HDPCVD method has been adjusted to have a lower ratio of depositing to etching than in the first or previous HDPCVD step to form the second silicon oxide layer.

In the inventive method, the second silicon oxide layer is formed with an HDPCVD process, which is without a bias voltage between plasma and wafer or only with a slight bias voltage. As a result thereof, an erosion of the deposited, second silicon oxide layer is reduced or even largely prevented. The deposition of the second silicon oxide layer even preferably occurs without erosion, i.e., without etching. Since the HDPCVD method is implemented with clearly reduced etching in the deposition of the second silicon oxide layer, layers and structures that are already present on the semiconductor substrate and, in particular, on the sidewalls and edges of the isolation trench are not damaged or, respectively, eroded. The reduced etching is achieved by means of a low bias voltage that can, in turn, be set via the power coupled into the plasma. The deposition of the second silicon oxide layer can occur without applying bias voltage in order to work practically without etching. The second silicon oxide layer should be deposited to a thickness that assures an adequate protection of the structures covered by the second silicon oxide layer in the following deposition of the third silicon oxide layer.

The bias voltage is increased only after deposition of the second silicon oxide layer to a predetermined thickness and then the isolation trench is completely filled with oxide with the third silicon oxide layer. As a result of the inventive method, damage that leads to a lowering of the cutoff voltage (array VT), to the leakage currents or to a gate oxide degradation (reduced GOX dependability) is avoided. Compared to the method disclosed in U.S. Pat. No. 6,037,018, the process of the present invention exhibits the advantage that the additional process step of U.S. Pat. No. 6,037,018, namely the application of the oxide protective layer by means of O₃-TEOS process, is avoided. In view of the process management in the manufacture of semiconductor components, this means a considerably lower outlay for material and time and, thus, a noteworthy saving of costs.

The inventive method, accordingly, initially works with a relatively high ratio of deposition to etching in the deposition of the silicon oxide with the HDPCVD method and subsequently works with a ratio that is low in comparison thereto. The erosion rate of the deposited silicon oxide is thereby clearly reduced at the beginning compared to the following deposition. The erosion rate can be set via the bias voltage between the wafer and the plasma and via the power coupled into the plasma. In the case of what is referred to as self-biasing, whereby the bias voltage is set from the ratio of the capacitances between the plasma and the wafer, on the one hand, and the plasma and the electrode lying opposite the wafer, on the other hand, the bias voltage is regulated by selecting the power that is coupled in. The deposition of the second and third silicon oxide layers can also occur directly following one another without interruption by means of a single HDPCVD process, whereby only the bias voltage is modified in the deposition of the second and third silicon oxide layers in the form of a single silicon oxide layer. The HDPCVD process, accordingly, is implemented in two steps. In the first step, the deposition occurs at a low or no bias voltage, whereas the bias voltage in the second step is increased up to the desired ratio of deposition to etching.

According to a preferred embodiment of the present invention, the isolation trench comprises a depth between 300 nm and 500 nm, particularly a depth between 350 nm and 450 nm.

In the embodiments having isolation trenches with a width of less than 0.3 μm, particularly a width of less than 0.2 μm are likewise preferred.

According to another preferred embodiment of the present invention, the oxide layer deposited without application of a RF voltage comprises a thickness between 20 nm and 200 nm. A thickness of the oxide layer between 40 nm and 150 nm is quite especially preferred. Since the oxide layer deposited without the application of a RF voltage should, on the one hand, exhibit a specific thickness in order to be able to dependably protect the structures lying therebelow during the HDPCVD process with the applied RF voltage and, on the other hand, the deposition without applied RF voltage can lead to an incomplete filling and cavities in the isolation trenches, the oxide layer deposited within the present invention without applied RF voltage that comprises a thickness between 60 nm and 100 nm, particularly a thickness between 70 nm and 90 nm, are quite specifically preferred. A thickness of approximately 80 nm is ideal.

The oxide layer subsequently deposited with the assistance of an applied RF voltage must completely fill the isolation trenches. Embodiments are therefore preferred wherein the oxide layer deposited with the assistance of an applied RF voltage comprises a thickness between 300 nm and 500 nm, and particularly a thickness between 350 nm and 450 nm.

Silicon oxide is preferably employed as a non-conductive material for filling the isolation trenches of the semiconductor component. Tetraethylorthosilicate (TEOS) is preferred as the Si source during application of the non-conductive layers.

The HDPCVD process to form the third layer has an applied RF voltage preferably implemented with a ratio of deposition to etching between 5.0 and 7.0, particularly a ratio of deposition to etching between 5.5 and 6.5. It is also preferred that when the HDPCVD process forming the second oxide layer is implemented with a ratio of deposition to etching of between 300 and 2000. In the HDPCVD process to form the second layer, an RF bias power of≦1 KW is preferably selected and the RF bias power of≦2 KW is selected during the depositing of the third layer.

Other advantages and features of the invention will be readily apparent from the following description of the preferred embodiments, the drawings and claims.

### BRIEF DESCRIPTION OF THE DRAWINGS

FIGS. 1A-1D are partial cross-sectional views of a semiconductor showing manufacturing steps for forming an isolation trench according to the prior art;

FIGS. 2A-2D are partial cross-sectional views of a semiconductor after various steps of another method for manufacturing an isolation trench according to the prior art;

FIGS. 3A and 3B are partial cross-sectional views illustrating a semiconductor device during certain steps in manufacturing an isolation trench according to a third method of the prior art;

FIG. 4 is a microphotograph of a transmission electron microscope illustrating damage produced by a traditional HDPCVD process for filling isolation trenches;

FIG. 5 is a partial cross-sectional view showing a method of the prior art for preventing damages shown in FIG. 4;

FIG. 6 is a partial cross sectional view of a semiconductor component after production of a field isolation trench with the inventive method; and

FIG. 7 is a microphotograph produced by a transmission electron microscope of a semiconductor component after generation of a filled isolation trench in accordance with the method of the present invention.

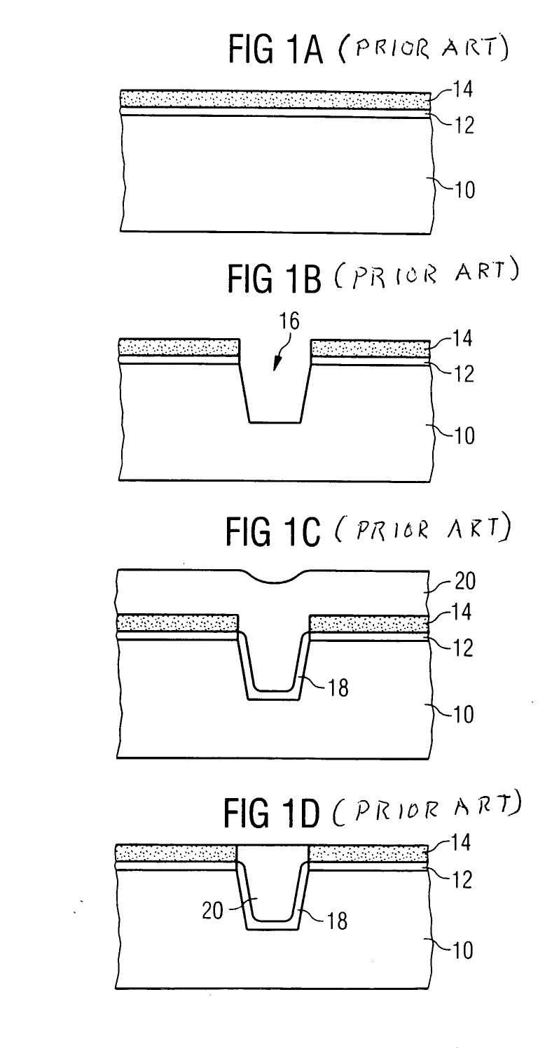

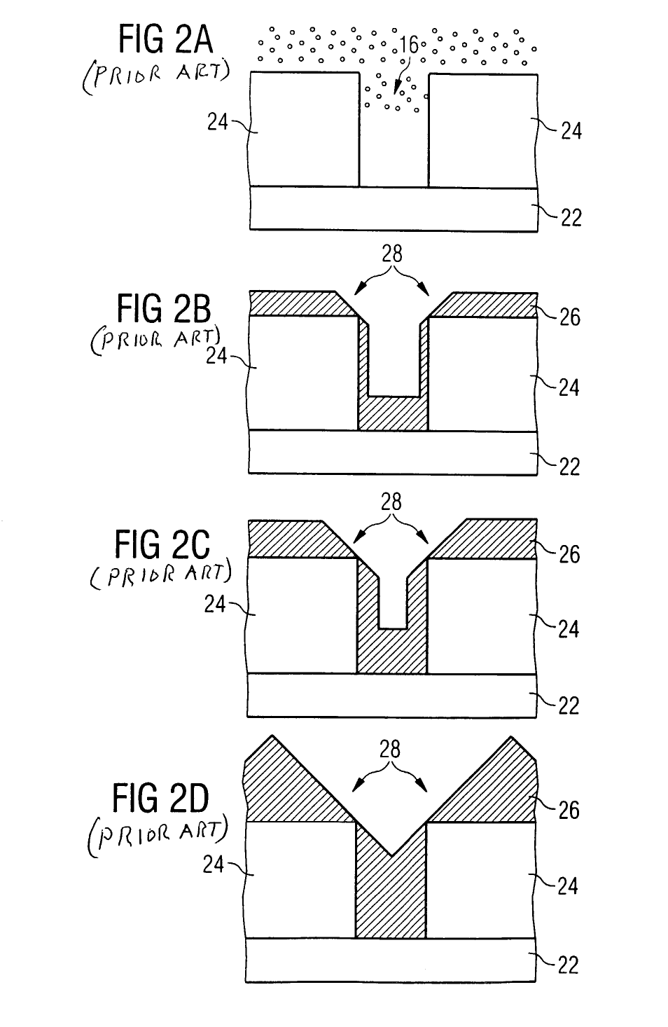

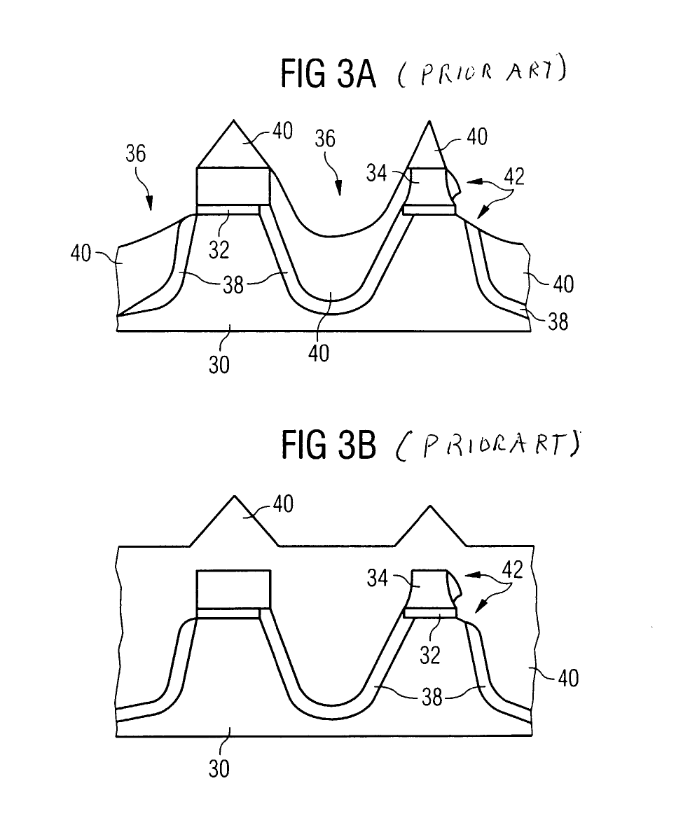

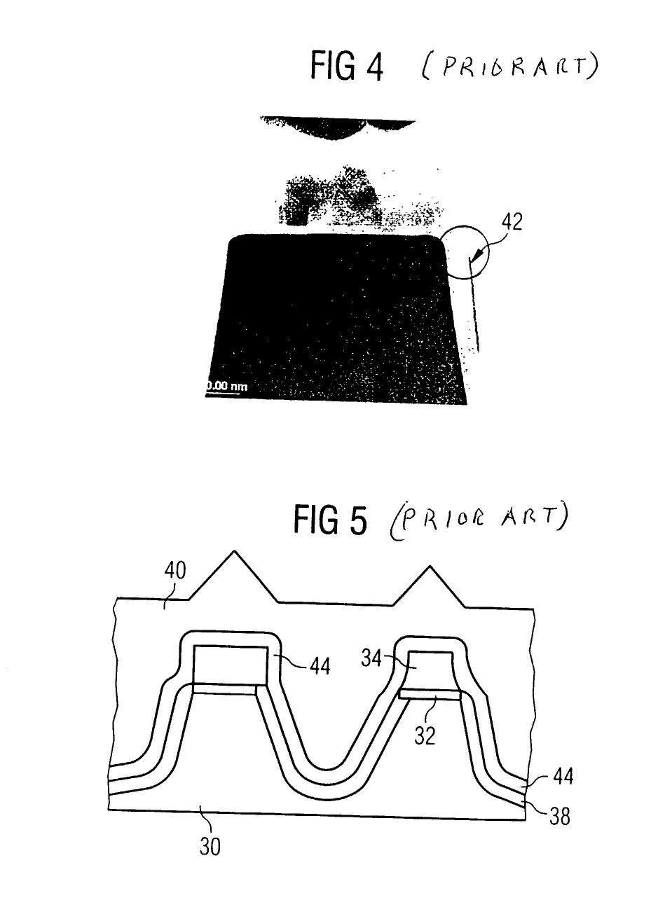

### DESCRIPTION OF THE PREFERRED EMBODIMENTS

The principles of the present invention are particularly useful to form a filled isolation trench, such as illustrated in FIG. 7.

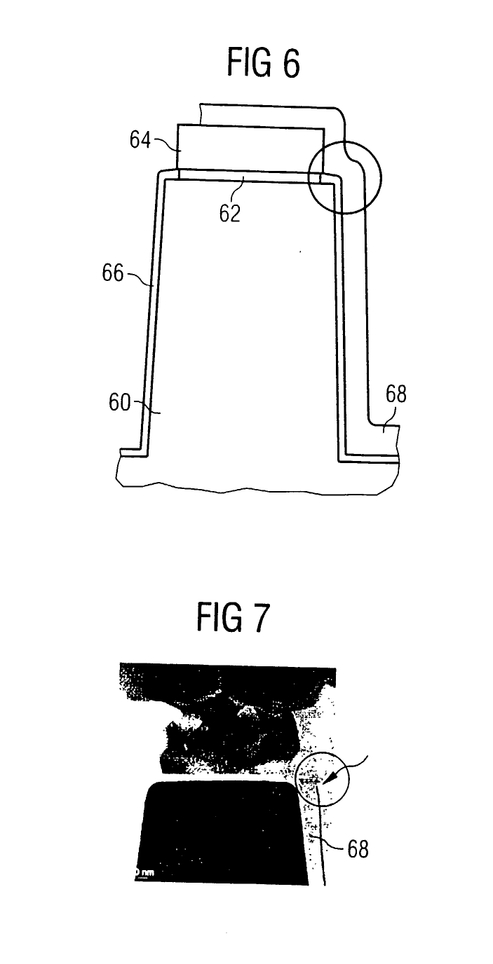

As shown in FIG. 6, a semiconductor substrate 60 has a trench etched into its surface leaving a pad oxide layer 62 and a pad nitride layer 64. Then, an oxide layer 66 is formed, such as described hereinabove. After forming the oxide layer 66, a second oxide layer 68 is applied during a HDPCVD process without the application of any RF voltage. The exposed corner is emphasized with a circle and is protected by the layer 68 against damage in the following HDPCVD step with the applied RF voltage.

The microphotograph with the filled isolation trench is illustrated in FIG. 7, and the exposed corner was protected against damage by the layer 68 in the HDPCVD step with applied RF voltage, with which the isolation trench was filled, and this exposed corner is emphasized by a circle. The intact layer 68 without damage can be seen from this microphotograph.

### EXAMPLE

For manufacturing an isolation trench filled with HDPCVD oxide, an isolation trench is first formed in a semiconductor substrate 60 by means of a dry-etching process. The dry-etching process is implemented with a power of 300-500 watts and a chamber of pressure of 40 mTorr through 60 mTorr. A flow of 5-15 sccm of CHF₃, 70-100 sccm of N₂ and 5-10 sccm of NF₃ is introduced into the chamber. To deposit a silicon oxide layer 66 at the sidewalls and on the floor of the isolation trench, heating is carried out to a temperature of 1000° C. for a time span of five minutes given a flow of 100 sccm of HCL and 10000 sccm of O₂.

A second silicon oxide layer 68 is subsequently formed at the sidewalls along the floor of the isolation trench by means of an HDPCVD process, whereby the bias RF power is less than 1 kilowatt, so that no bias voltage forms. In this step, a 60 nm thick layer is formed by introducing Ar, SiH₄ and O₂.

Subsequently, the third silicon oxide layer is deposited by means of an HDPCVD process, whereby a bias RF power of 2 through 3 kilowatts is applied, so that a bias voltage forms. In this step, a layer that is up to 500 nm thick is deposited by introducing Ar, SiH₄ and O₂.

Although various minor modifications may be suggested by those versed in the art, it should be understood that we wish to embody within the scope of the patent granted hereon all such modifications as reasonably and properly come within the scope of our contribution to the art.

We claim:

1. A method for manufacturing a high-density plasma-chemical vapor deposition oxide-filled isolation trench in a semiconductor substrate, said method comprising the steps of forming at least one isolation trench in the semiconductor substrate; forming a first silicon oxide layer at the sidewalls and on the floor of the isolation trench by an oxidation step; forming a second silicon oxide layer at the sidewalls and on the floor of the isolation trench by a high-density plasma-chemical vapor deposition method having a relatively high ratio of depositing to etching; and then forming a third silicon oxide layer to fill the isolation trench with silicon oxide by a high-density plasma-chemical vapor deposition method having a lower ratio of depositing to etching compared to the high ratio of the step for forming the second silicon oxide layer.

2. A method according to claim 1, wherein the isolation trench has a depth between 300 nm and 500 nm.

3. A method according to claim 2, wherein the isolation trench has a depth between 350 nm and 450 nm.

4. A method according to claim 2, wherein the isolation trench has a width of less than 0.3 μm.

5. A method according to claim 4, wherein the isolation trench has a width less than 0.2 μm.

6. A method according to claim 1, wherein the second oxide layer has a thickness in a range of 20 nm to 200 nm.

7. A method according to claim 6, wherein the thickness of the second oxide layer is between 40 nm and 150 nm.

8. A method according to claim 6, wherein the second oxide layer has a thickness between 60 nm and 100 nm.

9. A method according to claim 6, wherein the second oxide layer has a thickness between 70 nm and 90 nm.

10. A method according to claim 1, wherein the third oxide layer has a thickness between 300 nm and 500 nm.

11. A method according to claim 10, wherein the third oxide layer has a thickness between 350 nm and 450 nm.

12. A method according to claim 1, wherein tetraethylorthosilicate is the Si source in each of the high-density plasma-chemical vapor deposition processes.

13. A method according to claim 1, wherein the high-density plasma-chemical vapor deposition process to form the third silicon oxide layer is implemented with a ratio of depositing to etching of between 5.0 and 7.0.

14. A method according to claim 13, wherein the ratio is between 5.5 and 6.5.

15. A method according to claim 1, wherein the high-density plasma-chemical vapor deposition process for forming the second silicon oxide layer is implemented with a ratio of depositing to etching of between 300 and 2000.

16. A method according to claim 1, wherein the high-density plasma-chemical vapor deposition process for forming the second silicon oxide layer is performed with an RF bias power of≦1 KW and during forming the third silicon oxide layer, an RF bias power of≧2 KW is used for the high-density plasma-chemical vapor deposition process.

17. A method according to claim 1, wherein each of the isolation trenches has a width of less than 0.3 μm.

18. A method according to claim 17, wherein each of the isolation trenches has a width of less than 0.2 μm.
